(19) United States
(12) Patent Application Publication
(10) Pub. No.: US 2009/0296461 A1
(43) Pub. Date: Dec. 3, 2009

(54) Memory Devices and Related Data Storage Devices and Systems Including the Same

(76) Inventors: Sang Beom Kang, Gyeonggi-do (KR); Hyoung Seub Rhie, Gyeonggi-do (KR)

Correspondence Address: MYERS BIGEL SIBLEY & SAJOVEC, PO BOX 37428, RALEIGH, NC, 27627, US

(21) Appl. No.: 12/471,630

(22) Filed: May 26, 2009

(30) Foreign Application Priority Data
Jun. 2, 2008 (KR) 10-2008-0051453

(51) Int. Cl. G11C 11/14; H01L 29/82

(52) U.S. Cl. 365/171; 257/421; 257/E29.323

(57) ABSTRACT

Memory devices that include a semiconductor substrate defining a data storage area and a peripheral circuit area. A first magnetic memory device is provided in the peripheral area of the semiconductor substrate and is configured to exchange data signals externally. A second magnetic memory device is provided in the data storage area of the semiconductor substrate and is configured to exchange the data signals with the first magnetic memory device. Each portion of the first magnetic memory device and a portion of the second magnetic memory device include a magnetic tunnel junction structure having at least one magnetic layer. Related data storage devices and systems are also provided.

### CLAIM OF PRIORITY

This application claims the benefit of Korean Patent Application No. 10-2008-0051453, filed Jun. 2, 2008, the disclosure of which is hereby incorporated herein by reference as if set forth in its entirety.

### FIELD

The present invention relates generally to semiconductor memory devices and, more particularly, to semiconductor memory devices including magnetic memory devices and data storage device including the same.

### BACKGROUND

Generally, hard disk drives (HDDs) are data devices for reading and writing information using a read/write head that flies over a magnetic recording medium having a disc shape that rotates. The HDD is a high integration non-volatile data storage device. However, the mobility and reliability of the HDD may be deteriorated due to numerous mechanical systems embodied in the HDD. Furthermore, manufacturing costs and complexity typically increase and noise may be generated.

Recently, as a demand for data storage devices, such as, the HDD, capable of storing a large amount of data without including the mechanical system has increased, a data storage device using a magnetic memory device using a principle of movement of a magnetic domain wall of a magnetic material has been suggested. The magnetic memory device may be referred to as, for example, a magnetic track memory.

The magnetic track memory may be embodied by a high integration non-volatile data storage device, such as, the HDD. However, the read/write speed of the magnetic track memory is typically slower than that of a random access memory (RAM).

Accordingly, as conventional HDDs include a buffer cache area as an auxiliary role of a data storage area, the magnetic track memory may similarly include a buffer cache area. In other words, since it may take longer to store a large amount of data in the magnetic track memory, the large amount of data may be temporarily stored in the buffer cache area and then stored in the magnetic track memory.

The buffer cache area of the data storage device may be included in a non-volatile memory device, for example, a RAM. However, when power is cut off due to unexpected blackout or user's carelessness, the data stored in the buffer cache area may be lost.

### SUMMARY

Some embodiments of the present invention provide memory devices including a semiconductor substrate defining a data storage area and a peripheral circuit area. A first magnetic memory device is provided in the peripheral area of the semiconductor substrate and is configured to exchange data signals externally. A second magnetic memory device is provided in the data storage area of the semiconductor substrate and is configured to exchange the data signals with the first magnetic memory device. Each portion of the first magnetic memory device and a portion of the second magnetic memory device include a magnetic tunnel junction structure having at least one magnetic layer.

In further embodiments of the present invention, the first magnetic memory device may include a bit line configured to exchange a data signal and a first magnetic tunnel junction structure connected to the bit line and exchange the data signal.

In still further embodiments of the present invention, the first magnetic tunnel junction structure may include a fixed layer connected to a selection unit in the peripheral circuit area and having a magnetization direction fixed in one direction; an insulation layer on an upper surface of the fixed layer; and a free layer on an upper surface of the insulation layer, connected to the bit line, and having a magnetization direction that is a same magnetization direction as or an opposite magnetization direction to the magnetization direction of the fixed layer.

In some embodiments of the present invention, the magnetization direction of the free layer may be determined according to the data signal transmitted via the bit line.

In further embodiments of the present invention, the second magnetic memory device may include a memory track including a plurality of storage areas and a plurality of buffer areas adjacent to the plurality of storage areas, each of the plurality of storage areas having a plurality of magnetic domains and each of the plurality of magnetic domains having a different magnetization direction; and a second magnetic tunnel junction structure connected to one of the plurality of magnetic domains.

In still further embodiments of the present invention, the second magnetic tunnel junction structure may include a fixed layer connected to a selection unit in the data storage area and having a magnetization direction fixed in one direction; and an insulation layer on an upper surface of the fixed layer and connected to one of the plurality of magnetic domains. The magnetization direction of the one of the plurality of magnetic domains connected to the insulation layer may be a same magnetization direction as or an opposite magnetization direction to the magnetization direction of the fixed layer.

In some embodiments of the present invention, the one of the plurality of magnetic domains connected to the insulation layer may form a free layer of the second magnetic tunnel junction structure.

In further embodiments of the present invention, the second magnetic memory device may further include an input unit that is connected to the memory track and configured to provide a movement signal to horizontally move the plurality of magnetic domains. The magnetization direction of one of the plurality of magnetic domains connected to the second magnetic tunnel junction structure may be determined according to the movement signal provided by the input unit.

In still further embodiments of the present invention, the magnetic tunnel junction structure of the first magnetic memory device and the magnetic tunnel junction structure of the second magnetic memory device may be formed using a similar process.

In some embodiments of the present invention, the first magnetic memory device may be a magnetic random access memory (MRAM) and the second magnetic memory device may be a magnetic track memory.

Although embodiments of the present invention are primarily discussed above with respect to memory devices, related data storage devices and data storage systems are also provided.

### BRIEF DESCRIPTION OF THE DRAWINGS

Exemplary embodiments of the inventive concept will be more clearly understood from the following detailed description taken in conjunction with the accompanying drawings in which:

FIG. 1 is block diagram illustrating a memory device according to some embodiments of the present invention.

FIG. 2 is a cross-section illustrating the memory device of FIG. 1 in accordance with some embodiments of the present invention.

FIG. 3 is a perspective view illustrating a first magnetic tunnel junction structure of FIG. 2 in accordance with some embodiments of the present invention.

FIGS. 4A and 4B are cross-sections of the first magnetic tunnel junction structure of FIG. 3 illustrating operations of the first magnetic tunnel junction structure in accordance with some embodiments of the present invention.

FIG. 5 is a perspective view illustrating a second magnetic tunnel junction structure of FIG. 2 in accordance with some embodiments of the present invention.

FIGS. 6A and 6B are cross-sections of the second magnetic tunnel junction structure of FIG. 5 illustrating operations of the second magnetic tunnel junction structure in accordance with some embodiments of the present invention.

FIG. 7 is a block diagram of a data storage device including the memory device of FIG. 1 in accordance with some embodiments of the present invention.

FIG. 8 is a block diagram of a data storage system including the data device of FIG. 7 in accordance with some embodiments of the present invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

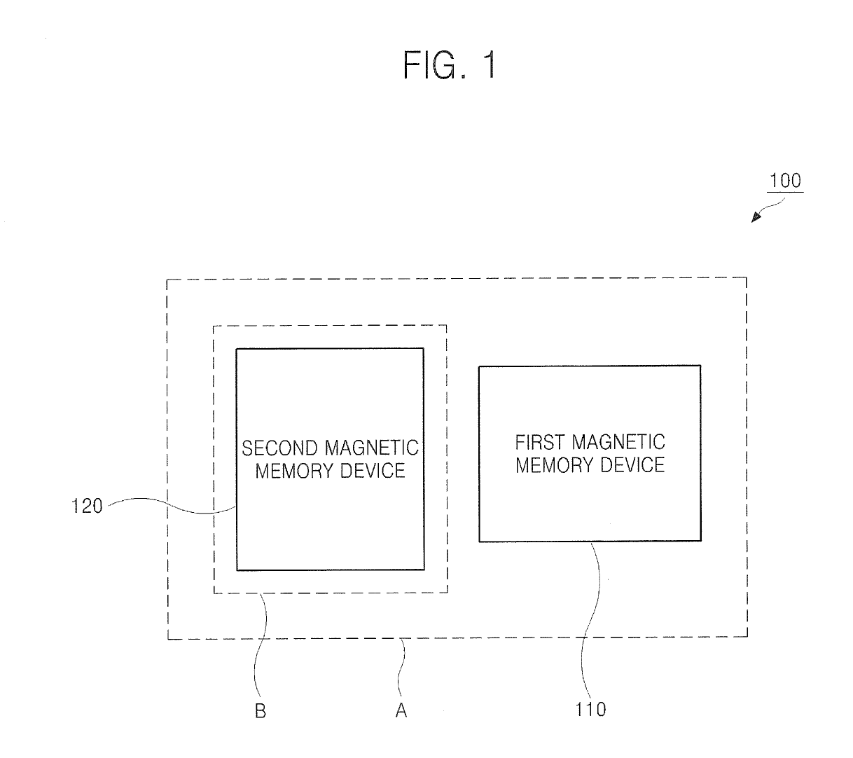

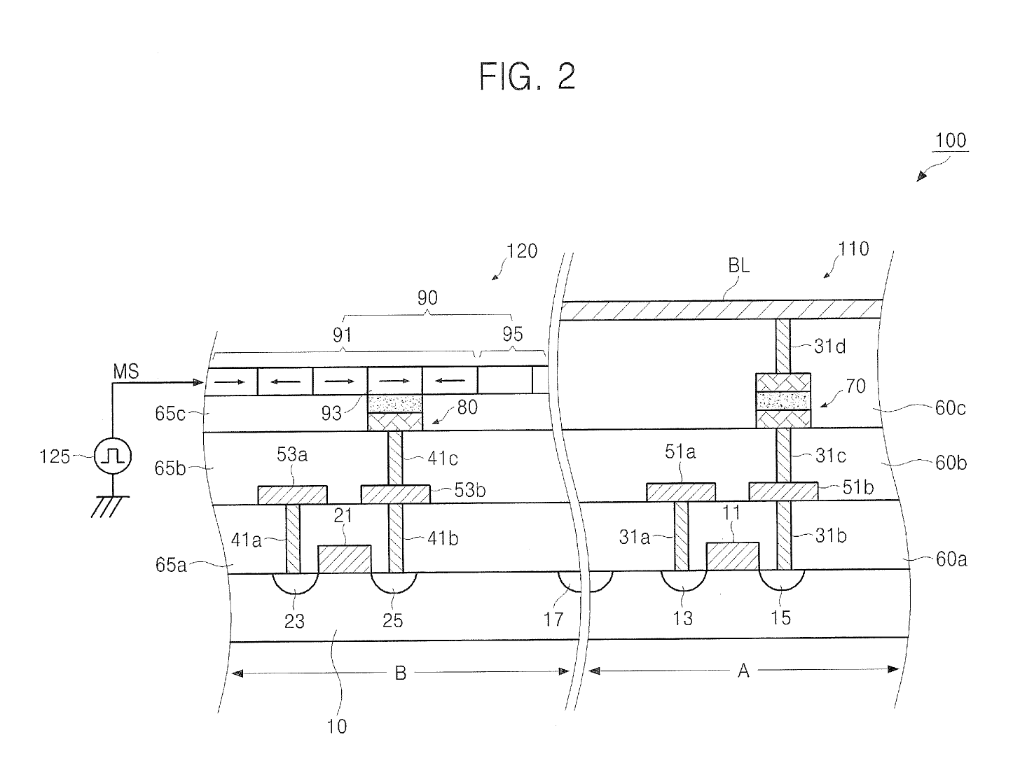

Referring now to FIG. 1, a block diagram illustrating a memory device 100 according to some embodiments of the present invention will be discussed. As illustrated in FIG. 1, the memory device 100 may include a data storage area B and a peripheral circuit area A. The data storage area B and the peripheral circuit area A may be defined by an isolation area 17 of FIG. 2 formed on, for example, a semiconductor substrate 10 of FIG. 2.

A second magnetic memory device 120 having a plurality of storage areas may be formed in the data storage area B. The second magnetic memory device 120 may exchange data signals with a first magnetic memory device 110 which will be described later. The second magnetic memory device 120 may be embodied by, for example, a magnetic track memory.

The first magnetic memory device 110 may be formed in the peripheral circuit area A. The first magnetic memory device 110 may exchange data signals externally and perform a buffer operation. For example, the first magnetic memory device 110 may temporarily store a data signal provided by an external device (not shown) in the first magnetic memory device 110 and provide the stored data signal to the second magnetic memory device 120, or may temporarily store a data signal to be provided to the external device in the first magnetic memory device 110 and output the stored data signal the external device. The first magnetic memory device 110 may be embodied by, for example, a magnetic random access memory (MRAM). Although it is not illustrated in the drawings, the memory device 100 may further include a plurality of interface circuits (not shown) that interface with the first and second magnetic memory devices 110 and 120.

FIG. 2 is a cross-section of the memory device 100 of FIG. 1. Referring now to FIGS. 1 and 2, the memory device 100 may include the first and second magnetic memory devices 110 and 120 which are formed on the semiconductor substrate 10. The first and second magnetic memory devices 110 and 120 may be separated by the isolation area 17 formed on the semiconductor substrate 10.

The semiconductor substrate 10 may be formed of at least one semiconductor material selected from Ge, SiGe, GaP, GaAs, SiC, SiGeC, InAs, and InP, but the present inventive concept is not limited thereto. Also, a SOI substrate may be used as the semiconductor substrate 10. The first magnetic memory device 110 is formed in the peripheral circuit area A of the semiconductor substrate 10. The first magnetic memory device 110 includes first selection portions 11, 13, and 15, a first magnetic tunnel junction (MTJ) structure 70, and a bit line BL. The first selection portions 11, 13, and 15 are formed in the peripheral circuit area A of the semiconductor substrate 10. The first selection portions 11, 13, and 15 may be a gate electrode 11, a source electrode 13, and a drain electrode 15, respectively.

The first selection portions 11, 13, and 15 may be formed through an oxidation process, a deposition process, an etching process, and an impurity injection process with respect to the semiconductor substrate 10. For example, a gate insulation layer (not shown) and the gate electrode 11 may be formed through the oxidation process with respect to the semiconductor substrate 10 and the deposition and etching processes with respect to a conductive material. Next, by using a predetermined ion injection process, a first impurity junction, for example, the source electrode 13, is formed in the semiconductor substrate 10 under one side of the gate electrode 11 and a second impurity junction, for example, the drain electrode 15, is formed in the semiconductor substrate 10 under the other side of the gate electrode 11. The source electrode 13 and the drain electrode 15 may be doped to the conductive type opposite to the semiconductor substrate 10. For example, when the semiconductor substrate 10 is a P type, the source electrode 14 and the drain electrode 15 may be doped to an N type.

A first interlayer insulation layer 60a may be formed on the semiconductor substrate 10 where the first selection portions 11, 13, and 15 are formed. The first interlayer insulation layer 60a may be formed by depositing such as a silicon oxide layer on the semiconductor substrate 10 using a chemical vapor deposition (CVD) method.

Parts of the first interlayer insulation layer 60a are removed by an etching process, for example, a dry etching process, so that the source electrode 13 and the drain electrode 15 may be exposed by the first interlayer insulation layer 60a. In other words, contact holes to expose predetermined contact holes (not shown), for example, the source electrode 13 and the drain electrode 15, may be formed by removing the parts of the first interlayer insulation layer 60a by an etching process.

Next, a predetermined conductive material is deposited to fill up the contact holes, thereby forming a first plug 31a and a second plug 31b. A first conductive layer 51a may be formed on the first plug 31a of the first interlayer insulation layer 60a and a second conductive layer 51b may be formed on the second plug 31b. That is, the first conductive layer 51a may be connected to the source electrode 13 via the first plug 31a and the second conductive layer 51b may be connected to the drain electrode 15 via the second plug 31b.

A second interlayer insulation layer 60b may be formed on top of the first interlayer insulation layer 60a in which the first and second conductive layers 51a and 51b are formed. Also, a contact hole (not shown) may be formed by removing a part of the second interlayer insulation layer 60b by an etching process to expose a part of the second interlayer insulation layer 60b, for example, the second conductive layer 51b. A predetermined conductive material, for example, a third plug 31c, may be formed to fill up the contact hole. The third plug 31c may be connected to the second conductive layer 51b.

The first magnetic tunnel junction structure 70 may be formed on top of the second interlayer insulation layer 60b, in which the third plug 31c is formed, to be connected to the third plug 31c. The first magnetic tunnel junction structure 70 may be formed by depositing, for example, at least one magnetic layer.

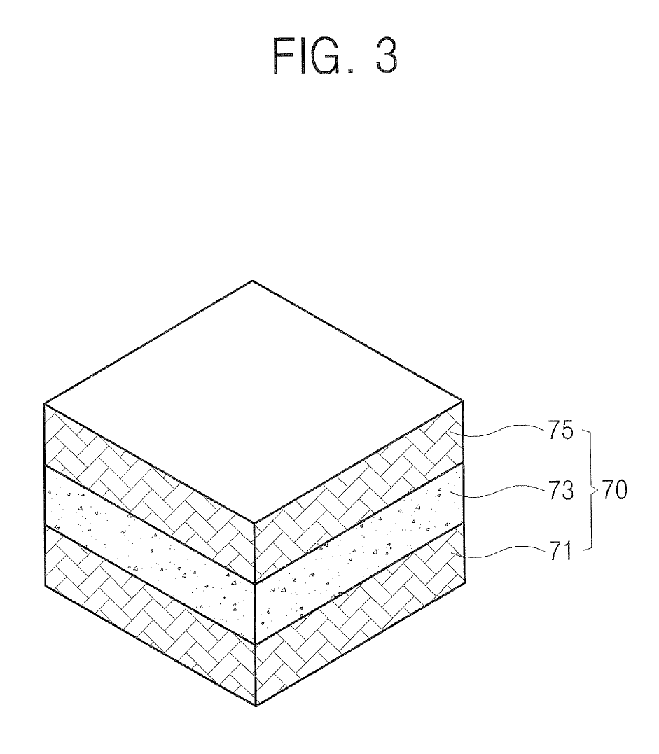

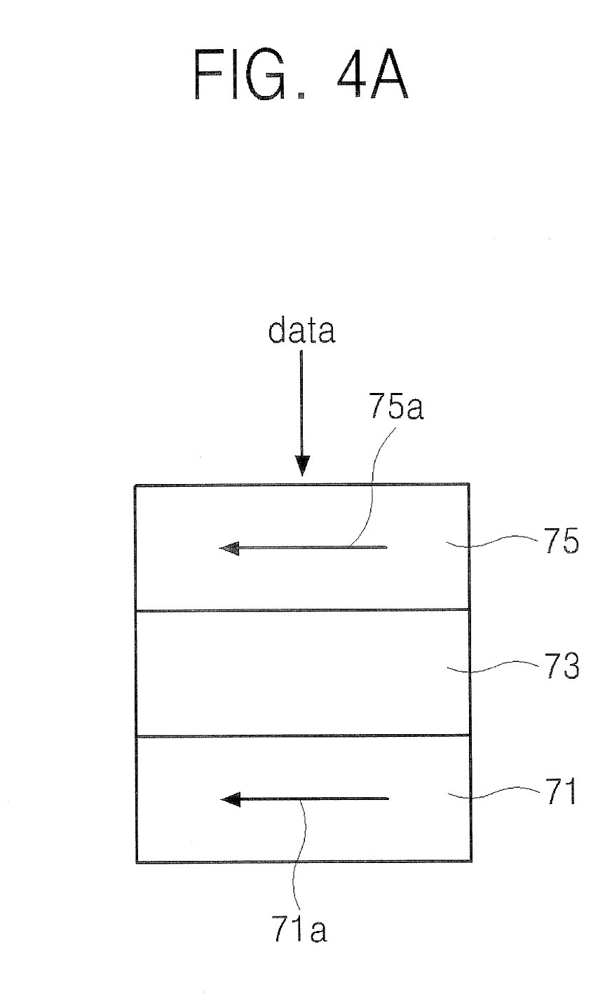

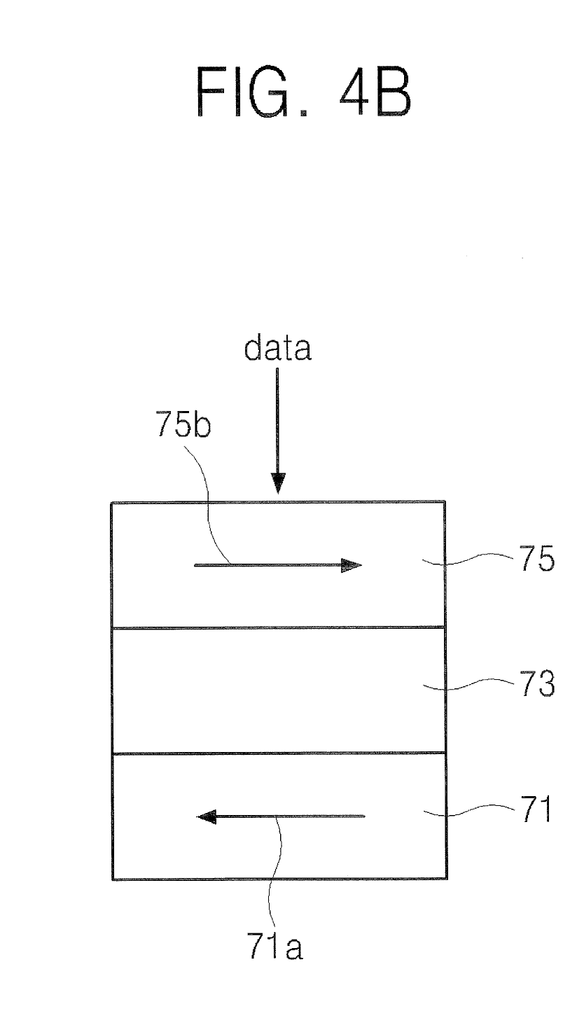

FIG. 3 is a perspective view illustrating the first magnetic tunnel junction structure of FIG. 2. FIGS. 4A and 4B are cross sections illustrating the operations of the first magnetic tunnel junction structure of FIG. 3. Referring now to FIGS. 2 and 3, the first magnetic tunnel junction structure 70 may include a first magnetic layer, for example, a fixed layer 71, an insulation layer 73, and a second magnetic layer, for example, a free layer 75.

The fixed layer 71 may be formed on top of the second interlayer insulation layer 60b to be connected to the third plug 31c. The fixed layer 71 may be a layer in which one magnetization direction is preferred, for example, the magnetization direction is fixed to one direction. The insulation layer 73 may be deposited on top of the fixed layer 71. The insulation layer 73 is provided between the free layer 75 to be described later and the fixed layer 71 and functions as a tunneling barrier between the free layer 75 and the fixed layer 71, for example, a tunneling barrier which greatly enables quantum mechanical tunneling of electrons.

The free layer 75 may be deposited on top of the insulation layer 73 and exchange data signals by being connected to the bit line BL to be described later. The free layer 75 may be a low magnetic layer in which the magnetization direction is not fixed compared to the fixed layer 71. The magnetization direction of the free layer 75 may be determined according to a magnetic field received from the bit line BL, for example, current of a data signal. The resistance of the first magnetic tunnel junction structure 70 including the fixed layer 71, the insulation layer 73, and the free layer 75 may be determined according to the magnetization direction between the fixed layer 71 and the free layer 75.

Referring to FIGS. 3 and 4A, the fixed layer 71 and the free layer 75 of the first magnetic tunnel junction structure 70 may have substantially the same direction, for example, magnetization directions 71a and 75a in a first direction. However, referring to FIGS. 3 and 4B, while the fixed layer 71 of the first magnetic tunnel junction structure 70 may have the magnetization direction 71a in the first direction, the free layer 75 may have the opposite direction to the magnetization direction 71a of the fixed layer 71, for example, a magnetization direction 75b in a second direction.

That is, when the magnetization direction 71a of the fixed layer 71 and the magnetization direction 75a of the free layer 75 are the same, the resistance of the first magnetic tunnel junction structure 70 is minimized. When the magnetization direction 71a of the fixed layer 71 and the magnetization direction 75b of the free layer 75 are opposite to each other, the resistance of the first magnetic tunnel junction structure 70 is maximized. Accordingly, information stored in the first magnetic tunnel junction structure 70 may be read out through detection current of the first magnetic tunnel junction structure 70.

Referring again to FIG. 2, a third interlayer insulation layer 60c is formed on top of the second interlayer insulation layer 60b in which the first magnetic tunnel junction structure 70 is formed. A contact hole (not shown) may be formed in the third interlayer insulation layer 60c by etching a part of the first magnetic tunnel junction structure 70, for example, a part of the free layer 75 of the first magnetic tunnel junction structure 70. Next, a predetermined conductive material, for example, a fourth plug 31d, may be formed to fill up the contact hole. The fourth plug 31d may be connected to the free layer 75 of the first magnetic tunnel junction structure 70. The first, second, and third interlayer insulation layers 60a, 60b, and 60c may be formed of the same material, for example, an insulation layer such as a silicon oxide layer, by a CVD method.

The bit line BL connected to the fourth plug 31d may be formed on top of the third interlayer insulation layer 60c. The bit line BL may exchange a data signal with the external device. Accordingly, the first magnetic memory device 110 including the first magnetic tunnel junction structure 70 may exchange the data signal via the bit line BL.

The second magnetic memory device 120 may be formed in the data storage area B of the semiconductor substrate 10. The second magnetic memory device 120 may include second selection portions 21, 23, and 25, a second magnetic tunnel junction structure 80, and a memory track 90. The second selection portions 21, 23, and 25 may be respectively formed substantially the same as the first selection portions 11, 13, and 15 formed in the peripheral circuit area A of the semiconductor substrate 10. The second selection portions 21, 23, and 25 may be formed by an oxidation process, a deposition process, an etching process, and an impurity injection process. The second selection portions 21, 23, and 25 may be a gate electrode 21, a source electrode 23, and a drain electrode 25, respectively.

A first interlayer insulation layer 65a is formed on top of the semiconductor substrate 10 where the second selection portions 21, 23, and 25 are formed. The source electrode 23 and the drain electrode 25 may be exposed by etching parts of the first interlayer insulation layer 65a. Next, a first plug 41a and a second plug 41b, respectively, connected to the source electrode 23 and the drain electrode 25 may be formed.

The first conductive layer 53a may be formed on top of the first interlayer insulation layer 65a to be connected to the first plug 41a. The second conductive layer 53b may be formed on top of the first interlayer insulation layer 65a to be connected to the second plug 41b. That is, the first conductive layer 53a may be connected to the source electrode 23 via the first plug 41a. The second conductive layer 53b may be connected to the drain electrode 25 via the second plug 41b.

A second interlayer insulation layer 65b may be formed on top of the first interlayer insulation layer 65a in which the first and second conductive layers 53a and 53b are formed. A part of the second interlayer insulation layer 65b may be etched off so that the second conductive layer 53b may be exposed. Next, a third plug 41c connected to the second conductive layer 53b that is exposed may be formed. The third plug 41c may be connected to the second conductive layer 53b.

The above-described processes, for example, the forming of the second selection portions 21, 23, and 25 in the data storage area B of the semiconductor substrate 10 and the forming of the first and second conductive layers 53a and 53b connected to the second selection portions 21, 23, and 25 may be formed in substantially the same processes as the processes for the first magnetic memory device 110, for example, the forming of the first selection portion 11, 13, and 15 in the peripheral circuit area A of the semiconductor substrate 10 and the forming of the first and second conductive layers 51a and 51b connected to the first selection portions 11, 13, and 15.

A second magnetic tunnel junction structure 80 may be formed on top of the second interlayer insulation layer 65b, in which the third plug 41c is formed, to be connected to the third plug 41c. The second magnetic tunnel junction structure 80 may be formed by depositing, for example, at least one magnetic layer.

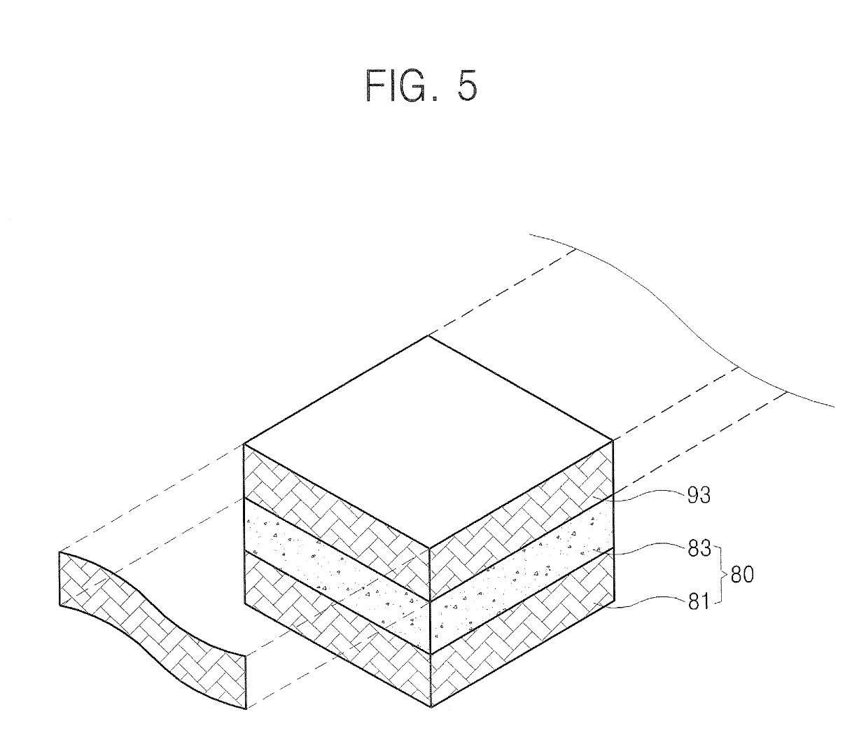

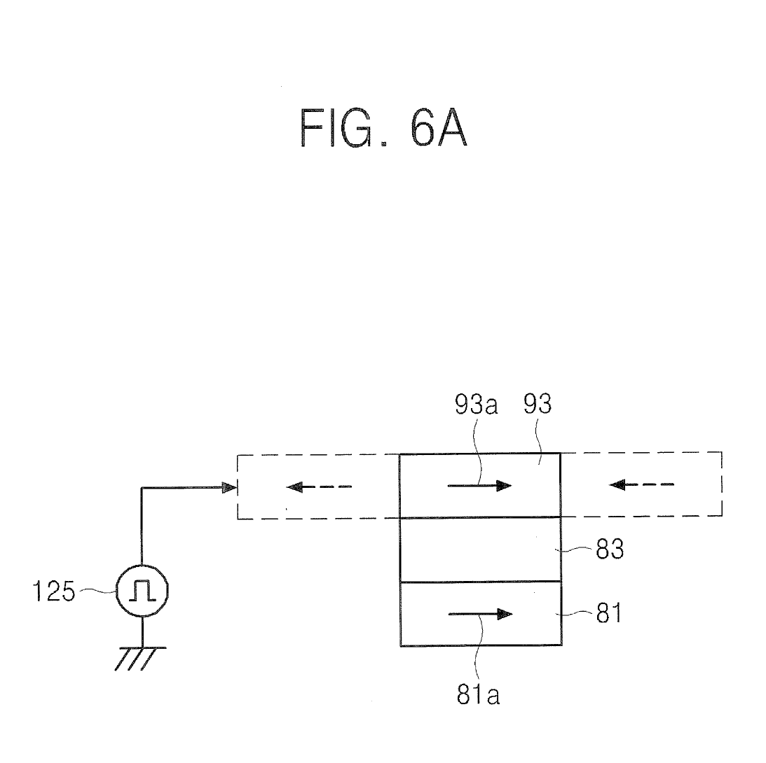

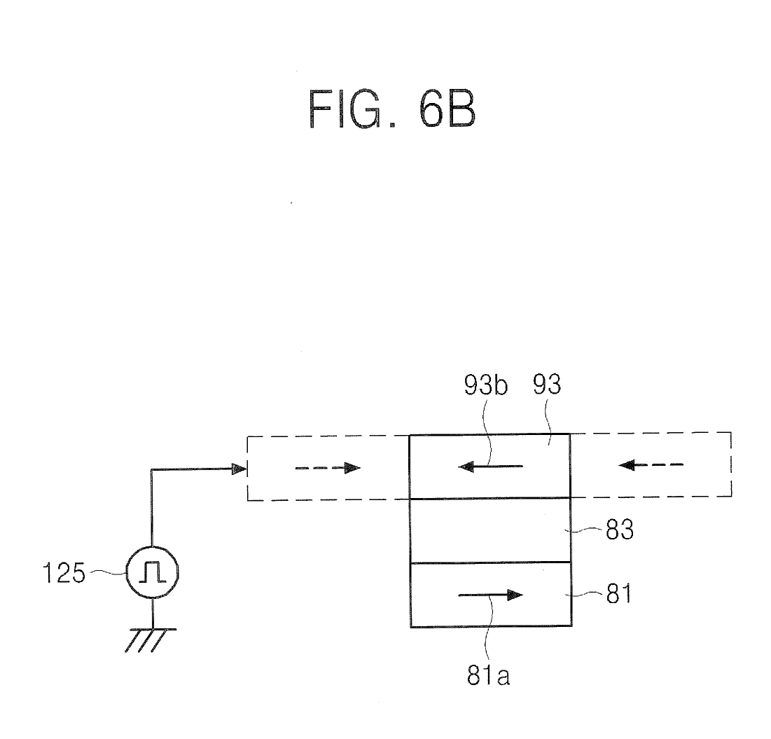

FIG. 5 is a perspective view of the second magnetic tunnel junction structure 80 of FIG. 2. FIGS. 6A and 6B illustrate the operation of the second magnetic tunnel junction structure 80 of FIG. 5. Referring to FIGS. 2 and 5, the second magnetic tunnel junction structure 80 may include a first magnetic layer, for example, a fixed layer 81, and an insulation layer 83. A second magnetic layer, for example, a free layer, of the second magnetic tunnel junction structure 80 may be formed by one of a plurality of magnetic domains 93 of the memory track 90 to be described above, which is connected to the insulation layer 83 of the second magnetic tunnel junction structure 80.

The fixed layer 81 may be formed on top of the second interlayer insulation layer 65b to be connected to the third plug 41c. The fixed layer 81 may be a layer in which one magnetization direction is preferred, for example, the magnetization direction is fixed to one direction. The insulation layer 83 may be deposited on top of the fixed layer 81. The insulation layer 83 is provided between the free layer to be described later, for example, one of the magnetic domains 93, and the fixed layer 81 and functions as a tunneling barrier, for example, a tunneling barrier which greatly enables quantum mechanical tunneling of electrons.

The second magnetic tunnel junction structure 80 may be formed in substantially the same process as that for the first magnetic tunnel junction structure 70 described with reference to FIGS. 1 through 4B. That is, the fixed layer 81 and the insulation layer 83 of the second magnetic tunnel junction structure 80 may be formed of substantially the same material as that of the fixed layer 71 and the insulation layer 73 of the first magnetic tunnel junction structure 70, and simultaneously formed in the same process. The resistance of the second magnetic tunnel junction structure 80 including the above-described fixed layer 81 and the insulation layer 83 may be determined according to the magnetization direction between the fixed layer 81 and one of the magnetic domains 93 connected to the insulation layer 83.

Referring to FIGS. 5 and 6A, the fixed layer 81 of the second magnetic tunnel junction structure 80 may have a magnetization direction 81a in a first direction. The one of the magnetic domains 93 connected to the insulation layer 83 may have substantially the same magnetization direction as that of the fixed layer 81 of the second magnetic tunnel junction structure 80, for example, a magnetization direction 93a in the first direction. However, referring to FIGS. 5 and 6B, while the fixed layer 81 of the second magnetic tunnel junction structure 80 may have the magnetization direction 81a in the first direction, the one of the magnetic domains 93 connected to the insulation layer 83 may have the opposite direction to the magnetization direction 81a of the fixed layer 81 of the second magnetic tunnel junction structure 80, for example, a magnetization direction 93b in a second direction, according to a movement signal MS provided by an input unit 125 to be described layer.

That is, when the magnetization direction 81a of the fixed layer 81 is the same as the magnetization direction 93a of one of the magnetic domains 93, for example, the one of the magnetic domains 93 forming the free layer by being connected to the insulation layer 83 of the second magnetic tunnel junction structure 80, the resistance of the second magnetic tunnel junction structure 80 is minimized. When the magnetization direction 81a of the fixed layer 81 is opposite to the magnetization direction 93b of one of the magnetic domains 93, the resistance of the second magnetic tunnel junction structure 80 is maximized. Accordingly, information stored in the second magnetic tunnel junction structure 80 may be read out through a detection current of the second magnetic tunnel junction structure 80.

Referring again to FIG. 2, a third interlayer insulation layer 65c is formed on top of the second interlayer insulation layer 65b in which the second magnetic tunnel junction structure 80 is formed. The third interlayer insulation layer 65c may be etched off such that a part of the second magnetic tunnel junction structure 80, for example, the insulation layer 83 of the second magnetic tunnel junction structure 80, may be exposed. The memory track 90 that is partially connected to the second magnetic tunnel junction structure 80 that is exposed may be formed on top of the third interlayer insulation layer 65c in which a part of the second magnetic tunnel junction structure 80 is exposed. The memory track 90 may include a plurality of storage areas 91 and a plurality of buffer areas 95 adjacent to the storage areas 91.

Each of the storage areas 91 may include the magnetic domains 93. Each of the magnetic domains 93 may store a multi-bit data signal. Each of the magnetic domains 93 may be divided by a magnetic domain wall, for example, a magnetic domain wall, formed on the memory track 90, and may have a different magnetization direction. For example, each of the magnetic domains 93 may have a horizontal magnetization direction or a vertical magnetization direction. In the present embodiment, the magnetic domains 93, each having a horizontal magnetization direction, is described.

The buffer areas 95 adjacent to the storage areas 91 that are formed of the magnetic domains 93 may temporarily store the data signal to be stored in the storage areas 91. For example, the buffer areas 95 may temporarily store the data signal moving out of the storage areas 91 when the magnetic domains 93 horizontally move according to a movement signal MS that is externally provided by, for example, an input unit 125.

The second magnetic memory device 120 may further include the input unit 125. The input unit 125 may be connected to the memory track 90 and output the movement signal MS to move the magnetic domains 93 of the memory track 90. For example, the movement signal MS output from the input unit 125 may horizontally move the magnetic domains 93. That is, the magnetization directions of the magnetic domains 93 of the memory track 90 according to the movement signal MS provided by the input unit 125 to the memory track 90 may be moved to the magnetic domains 93 adjacent thereto, which is referred to as magnetic domain movement.

Of the magnetic domains 93 horizontally moving according to the movement signal MS provided by the input unit 125, the magnetic domain 93 correspondingly connected to the insulation layer 83 of the second magnetic tunnel junction structure 80 may be formed into the free layer of the second magnetic tunnel junction structure 80. For example, the magnetic domains 93 having different magnetization directions may be horizontally moved according to an input signal provided by the input unit 125. The magnetic domain 93 connected to the insulation layer 83 of the second magnetic tunnel junction structure 80 of the magnetic domains 93 may be operated as the free layer of the second magnetic tunnel junction structure 80. That is, the amount of resistance of the second magnetic tunnel junction structure 80 may be determined according to whether the magnetization direction of the magnetic domain 93 operating as the free layer and the magnetization direction of the fixed layer 81 of the second magnetic tunnel junction structure 80 are the same or opposite to each other.

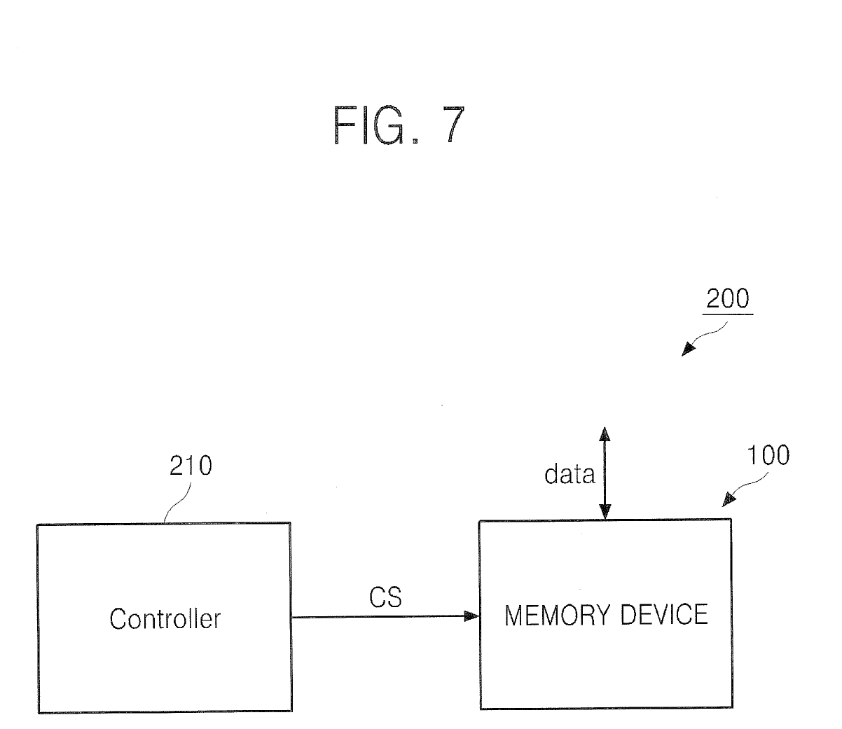

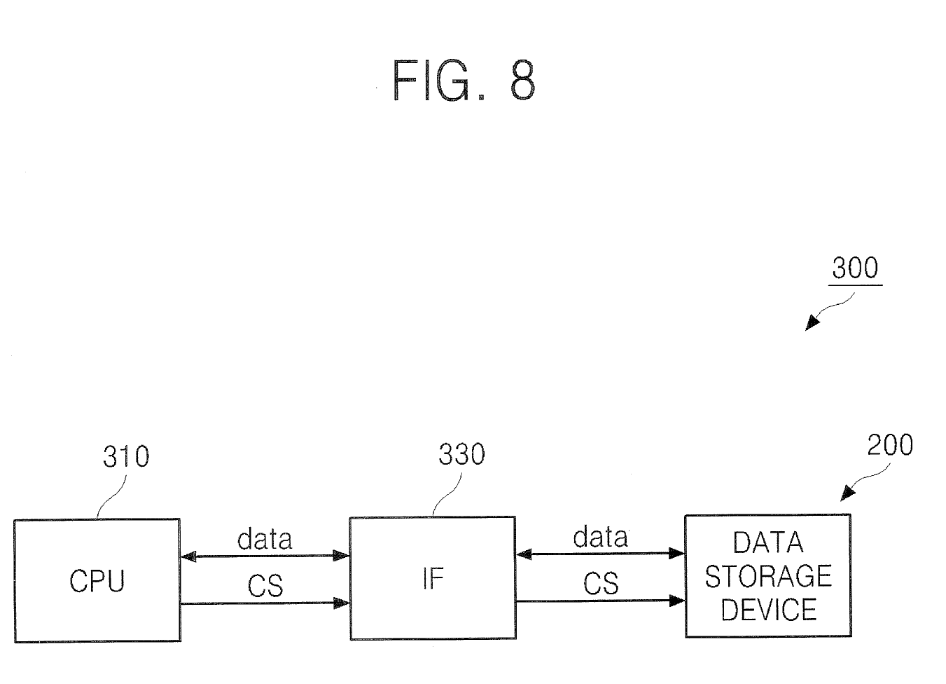

FIG. 7 is a block diagram of a data storage device including the memory device of FIG. 1. FIG. 8 is a block diagram of a data storage system including the data device of FIG. 7. Referring to FIG. 7, a data storage device 200 may include the memory device 100 and a controller 210.

The memory device 100 may include the first magnetic memory device 110 and the second magnetic memory device 120, as described above with reference to FIGS. 1-6. The memory device may exchange data signals (data) externally. For example, the first magnetic memory device 110 of the memory device 100 may function as a buffer for temporarily storing the data signal (data) provided by the external device. The second magnetic memory device 120 may function as a storage device for receiving the data signal (data) stored in the first magnetic memory device 110 that operates as a buffer.

The controller 210 may provide a control signal CS to control the operation of the memory device 100. That is, the controller 210 may output the control signal to control the memory device 100 to exchange the data signal (data) with the external device. The data signal (data) transmitting or storing operation of the memory device 100 may be controlled according to the control signal CS output from the controller 210.

Referring to FIG. 8, a data storage system 300 may include a CPU 310, an interface (IF) 330, and the data storage device 200. The data storage system 300 according to the present embodiment may include, for example, a personal computer (PC), a portable terminal, or a smart card. The data storage device 200 may be substantially the same as one described with reference to FIG. 7. The data storage device 200 may communicate with the CPU 310 via the interface 330 and store or externally output the data signal (data) according to the control signal CS provided by the CPU 310. The CPU 310 may communicate with the data storage device 200 via the interface 330, provide the control signal CS and the data signal (data) to the data storage device 200, and receive the data signal (data) from the data storage device 200.

As described above, in the memory device according to the present embodiment and the data storage device using the memory device, since the memory device is realized using two magnetic memory devices having a magnetic junction structure having at least one magnetic layer, each of the magnetic memory devices formed in the substantially same manufacturing process, the manufacturing process of the memory device may be simplified and the process cost may be reduced. Also, since a non-volatile magnetic memory device is used for the buffer area of the memory device, when power is cut off due to unexpected blackout or user's carelessness, the data stored in the buffer area may be prevented from being lost.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A memory device comprising:
a semiconductor substrate defining a data storage area and a peripheral circuit area;
a first magnetic memory device in the peripheral area of the semiconductor substrate and configured to exchange data signals externally; and
a second magnetic memory device in the data storage area of the semiconductor substrate and configured to exchange the data signals with the first magnetic memory device,
wherein each portion of the first magnetic memory device and a portion of the second magnetic memory device include a magnetic tunnel junction structure having at least one magnetic layer

2. The memory device of claim 1, wherein the first magnetic memory device comprises:
a bit line configured to exchange a data signal; and
a first magnetic tunnel junction structure connected to the bit line and configured to exchange the data signal.

3. The memory device of claim 2, wherein the first magnetic tunnel junction structure comprises:
a fixed layer connected to a selection unit in the peripheral circuit area and having a magnetization direction fixed in one direction;
an insulation layer on an upper surface of the fixed layer; and
a free layer on an upper surface of the insulation layer, connected to the bit line, and having a magnetization direction that is a same magnetization direction as or an opposite magnetization direction to the magnetization direction of the fixed layer.

4. The memory device of claim 3, wherein the magnetization direction of the free layer is determined according to the data signal transmitted via the bit line.

5. The memory device of claim 1, wherein the second magnetic memory device comprises:
a memory track including a plurality of storage areas and a plurality of buffer areas adjacent to the plurality of storage areas, each of the plurality of storage areas having a plurality of magnetic domains and each of the plurality of magnetic domains having a different magnetization direction; and
a second magnetic tunnel junction structure connected to one of the plurality of magnetic domains.

6. The memory device of claim 5, wherein the second magnetic tunnel junction structure comprises:
a fixed layer connected to a selection unit in the data storage area and having a magnetization direction fixed in one direction; and
an insulation layer on an upper surface of the fixed layer and connected to one of the plurality of magnetic domains,
wherein the magnetization direction of the one of the plurality of magnetic domains connected to the insulation layer is a same magnetization direction as or an opposite magnetization direction to the magnetization direction of the fixed layer.

7. The memory device of claim 6, wherein the one of the plurality of magnetic domains connected to the insulation layer forms a free layer of the second magnetic tunnel junction structure.

8. The memory device of claim 5, wherein the second magnetic memory device further comprises an input unit that is connected to the memory track and configured to provide a movement signal to horizontally move the plurality of magnetic domains, and wherein the magnetization direction of one of the plurality of magnetic domains connected to the second magnetic tunnel junction structure is determined according to the movement signal provided by the input unit.

9. The memory device of claim 1, wherein the magnetic tunnel junction structure of the first magnetic memory device and the magnetic tunnel junction structure of the second magnetic memory device are formed using a similar process.

10. The memory device of claim 1, wherein the first magnetic memory device is a magnetic random access memory (MRAM) and the second magnetic memory device is a magnetic track memory.

11. A data storage device comprising:
a memory device including a first magnetic memory device and a second magnetic memory device; and
a controller configured to output a control signal that controls operation of the memory device,
wherein the memory device comprises:
a semiconductor substrate defining a data storage area and a peripheral circuit area;
a first magnetic memory device in the peripheral area of the semiconductor substrate and configured to exchange data signals externally; and
a second magnetic memory device in the data storage area of the semiconductor substrate and configured to exchange the data signals with the first magnetic memory device,
wherein each of portion of the first magnetic memory device and a portion of the second magnetic memory device include a magnetic tunnel junction structure including at least one magnetic layer.

12. A data storage system comprising:
a central processing unit (CPU);
an interface configured to communicate with the CPU; and
a data storage device configured to communicate with the CPU via the interface,
wherein the data storage device comprises:
a memory device including a first magnetic memory device and a second magnetic memory device; and
a controller configured output a control signal to control operation of the memory device,
wherein the memory device comprises:
a semiconductor substrate defining a data storage area and a peripheral circuit area;
a first magnetic memory device in the peripheral area of the semiconductor substrate and configured to exchange data signals externally; and
a second magnetic memory device in the data storage area of the semiconductor substrate and configured to exchange the data signals with the first magnetic memory device,
wherein each of portion of the first magnetic memory device and a portion of the second magnetic memory device include a magnetic tunnel junction structure including at least one magnetic layer.
